(19) United States
(12) Patent Application Publication
(10) Pub. No.: US 2006/0150136 A1
(43) Pub. Date: Jul. 6, 2006

(54) Systems and methods for designing integrated circuits

(76) Inventors: John Bratt, Fort Collins, CO (US); Brett William, Windsor, CO (US); Jeffrey Rearick, Fort Collins, CO (US)

Correspondence Address: AGILENT TECHNOLOGIES, INC.;INTELLECTUAL PROPERTY ADMINISTRATION, LEGAL DEPT., P.O. BOX 7599, M/S DL429, LOVELAND, CO, 80537-0599, US

(21) Appl. No.: 11/314,569

(22) Filed: Dec. 21, 2005

Related U.S. Application Data
(60) Provisional application No. 60/637,913, filed on Dec. 21, 2004.

(51) Int. Cl. G06F 17/50; G01R 31/28

(52) U.S. Cl. 716/12; 716/4; 714/726

(57) ABSTRACT

Systems and methods for designing integrated circuits (ICs) are provided. A representative method includes: providing a netlist; determining components required to implement test of at least a portion of the integrated circuit defined by the netlist; provide a revised netlist including the components determined; and performing a place and route operation with respect to the revised netlist.

### CROSS REFERENCE TO RELATED APPLICATION

This application is a utility application that claims the benefit of and priority to U.S. Provisional patent application Ser. No. 60/637913, which was filed on Dec. 21, 2004, and which is incorporated herein by reference.

### BACKGROUND

Contemporary integrated circuit (IC) design typically beings with a behavioral description of an IC. For instance, a register transfer level (RTL) description of the IC can be used. Logic synthesis is performed on the RTL description in combination with various constraints, e.g., timing, area and/or power requirements of the IC. Logic synthesis of the RTL and associated constraints results in a Boolean description of the IC. Using the Boolean description, a netlist can be generated that specifies the logic gates and various interconnections of the IC. Based upon the structural characteristics, i.e., size and shape, of the gates and the specified gate interconnectivity of the netlist, the gates can be placed and routing of the various interconnections can be determined. This process is commonly known as “place and route.” Once the gates and interconnections have been placed and routed, functionality of the IC can be verified. For example, timing requirements of the IC can be checked to ensure that the IC will function as intended.

Once functionality has been verified, it is common to add components to the IC to facilitate test. However, adding components required for testing can significantly alter various aspects of the IC, e.g., functional and/or structural aspects, and can potentially cause an otherwise properly designed IC to fail to meet one or more of its design criteria. This typically results in one or more iterations of the above-described process that includes consideration of the components that need to be added to the IC for test.

In this regard, FIG. 1 is a schematic diagram that depicts a hierarchical description of an IC designed in accordance with contemporary IC design methodology described above. Note that the IC 10 includes major blocks or circuits, which are outlined with thick lines. In this example, 10 major blocks are shown, e.g., blocks 12 and 14. The major blocks are the top level of the hierarchy making up the IC 10.

Each major block includes sub-blocks or sub-circuits, e.g., sub-blocks 14A and 14B, outlined by lines of medium thickness. Each of the sub-blocks includes sub-sub-blocks, e.g., sub-sub-blocks 14BA and 14BB, outlined by thin lines. Also note that the hierarchy can be repeated all the way down to the logic gate level.

FIG. 2A illustrates the sub-sub-blocks 14BA and 14BB of the IC 10 of FIG. 1 in greater detail. Specifically, sub-sub-block 14BA includes logic circuitry 202 and flip-flops 204A through 204E. Likewise, sub-sub-block 14BB includes logic circuitry 212 and flip-flops 214A through 214E. No provision for test circuitry (e.g. a scan chain with associated scanin and scanout ports) has been made in this schematic of the circuit, and the physical implementation of this schematic will result in a placement and routing solution that may not leave room for the later addition of desired test circuitry. Such a later addition will likely result in significant rework to alter the physical implementation to accommodate the test circuitry.

FIG. 2B alternatively illustrates the sub-sub-blocks 14BA and 14BB of the IC 10 of FIG. 1 in greater detail, this time with test circuitry included in the schematic. Specifically, sub-sub-block 14BA includes logic circuitry 202, and flip-flops 204A through 204E. Note that flip-flop 204A includes a port 206 that is used as scan input and flip-flop 204E includes a port 208 that is used as a scan output. Similarly, sub-sub-block 14BB includes logic circuitry 212 and flip-flops 214A through 214F. Flip-flop 214A includes a port 216 that is used as a scan input and flip-flop 214E includes a port 218 that is used as a scan output. In this case, the separation of the sub-sub-blocks into two different hierarchical elements resulted in the addition of two separate scan chains along with their associated two sets of scanin and scanout ports, and the complete specification of the scan chain ordering may complicate optimal placement and routing.

In FIG. 2B, the design area allocated for sub-sub-blocks 14BA and 14BB has been exceeded. In particular, the trace interconnecting flip-flops 204B and 204C, and flip-flop 214E extend beyond the perimeter of the allocated area. Thus, adding components such as the flip-flops 204A through 204E and 214A through 214E in accordance with contemporary IC design methodology described above has caused the IC 10 to fail to meet at least one of its design criteria. Specifically, the design area allocated for sub-sub-blocks 14BA and 14BB has been exceeded. Failure to account for the additional circuitry, wiring, and connections required for testability considerations until late in the physical design of an integrated circuit may cause significant rework in the design process, and insertion and over-specification of test circuitry too early in the design process can cause undue design constraints to be imposed.

### SUMMARY

Systems and methods for designing integrated circuits (ICs) are provided. In this regard, a representative embodiment of a method comprises: providing a netlist; determining components required to implement test of at least a portion of the integrated circuit defined by the netlist; provide a revised netlist including the components determined; and performing a place and route operation with respect to the revised netlist.

Computer-readable media also are provided that store information for performing computer-implemented methods. In this regard, a representative computer-readable medium has stored thereon information for performing a computer-implemented method, the method comprising: providing a netlist; determining components required to implement test of at least a portion of the integrated circuit defined by the netlist; provide a revised netlist including the components determined; and performing a place and route operation with respect to the revised netlist.

A representative embodiment of a system for designing an integrated circuit comprises a processor operative to execute instructions; and a memory communicating with the processor and storing instructions for: providing a netlist; determining components required to implement test of at least a portion of the integrated circuit defined by the netlist; providing a revised netlist including the components determined; and performing a place and route operation with respect to the revised netlist.

Other systems, methods, features and/or advantages will be or may become apparent to one with skill in the art upon examination of the following drawings and detailed description. It is intended that all such additional systems, methods, features and/or advantages be included within this description and be protected by the accompanying claims.

### BRIEF DESCRIPTION OF THE DRAWINGS

The components in the drawings are not necessarily to scale relative to each other. Like reference numerals designate corresponding parts throughout the several views.

FIG. 1 is a schematic diagram depicting a hierarchical layout of a portion of an integrated circuit designed using a prior art IC design methodology.

FIG. 2A is a schematic diagram depicting a portion of the integrated circuit of FIG. 1 without any test structures.

FIG. 2B is a schematic diagram depicting a portion of the integrated circuit of FIG. 1 after the addition of test components in accordance with the prior art IC design methodology.

FIG. 3 is a schematic diagram depicting a hierarchical layout of an integrated circuit.

FIG. 4 is a schematic diagram depicting a portion of the integrated circuit of FIG. 3 after the addition of test components.

FIG. 5 is a flowchart depicting functionality of an embodiment of a system for designing integrated circuits.

FIG. 6 is a flowchart depicting functionality of an embodiment of a method for designing integrated circuits.

FIG. 7 is a schematic diagram depicting a computer or processor based device that can be used to implement an embodiment of a system for designing integrated circuits.

### DETAILED DESCRIPTION

As will be described in detail here, systems and methods for designing integrated circuits (ICs) can be used to design ICs that meet desired design criteria, even after incorporating components, e.g., logic gates, registers, and corresponding interconnectivity, required for facilitating IC test. In this regard, embodiments of the systems and methods account for additional components that are used to facilitate test functionality earlier in the design process than is implemented in the prior art. Thus, timing, area and/or power requirements, for example, of these additional components can be considered during an early place and route operation and can potentially alleviate one or more iterations of a conventional IC design process.

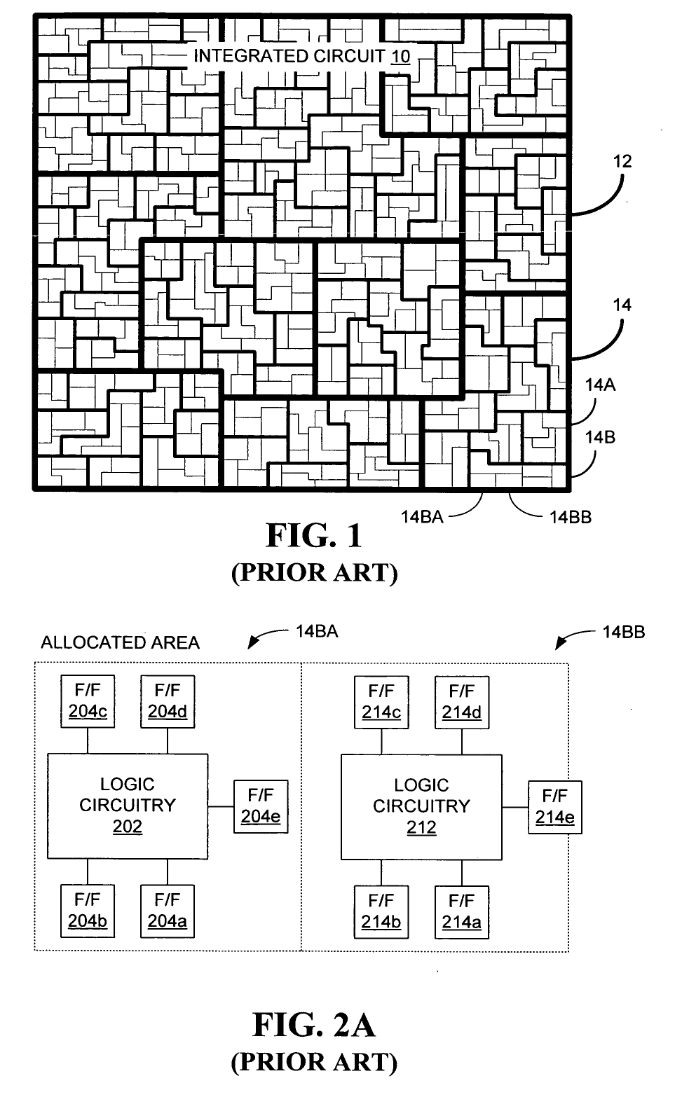

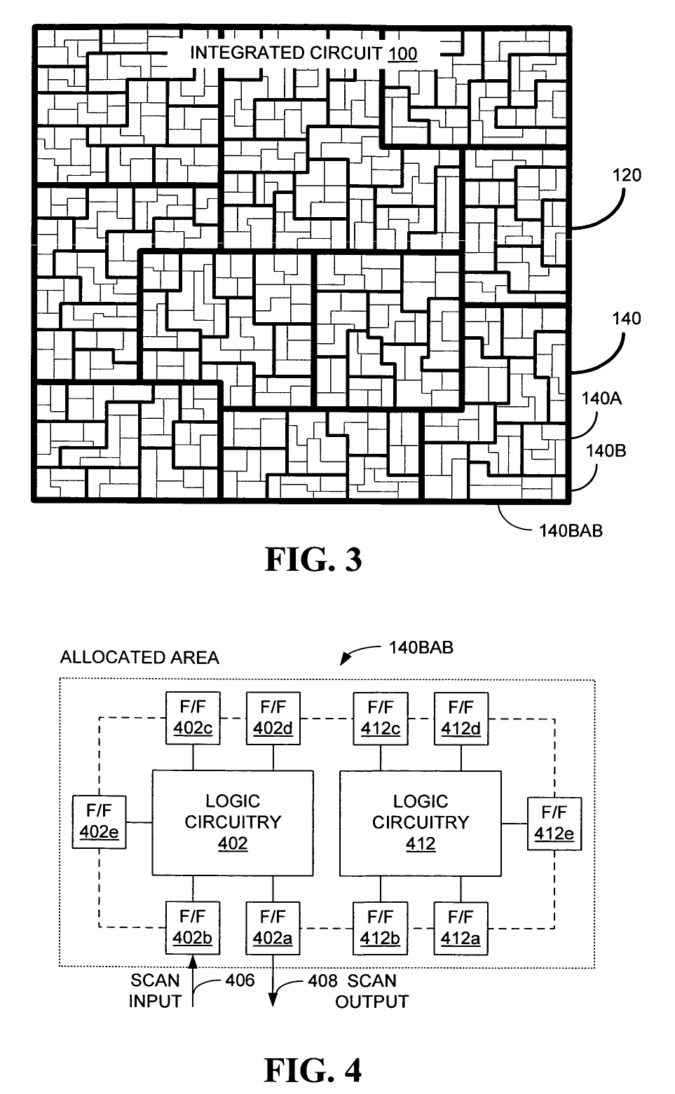

Referring again to the drawings, FIG. 3 is a schematic diagram depicting a hierarchical layout of an integrated circuit 100. In the same manner as FIG. 1, the IC 100 includes major blocks or circuits, which are outlined with thick lines. In this example, 10 major blocks are shown, e.g., blocks 120 and 140. The major blocks are the top level of the hierarchy making up the IC 100.

Each major block includes sub-blocks or sub-circuits, e.g., sub-blocks 140A and 140B, outlined by lines of medium thickness. Each of the sub-blocks includes sub-sub-blocks, e.g., sub-sub-block 14BAB, outlined by thin lines. In contrast to the IC of FIG. 1 in which sub-block 14B contained sub-sub-blocks 14BA and 14BB, among others, the IC of FIG. 3 has a revised hierarchy in which those two sub-sub-blocks were merged into a single unit 140BAB.

FIG. 4 illustrates the sub-sub-block 140BAB of the IC 100 of FIG. 3 in greater detail. Specifically, sub-sub-block 140BAB includes logic circuitry 402, and flip-flops 404A through 404E, as well as logic circuitry 412 and flip-flops 214A through 214E. A single scan chain in the dashed line originating at scan input port 406 and terminating at scan output port 408 connects all ten flip-flops in the merged sub-sub-block 140BAB.

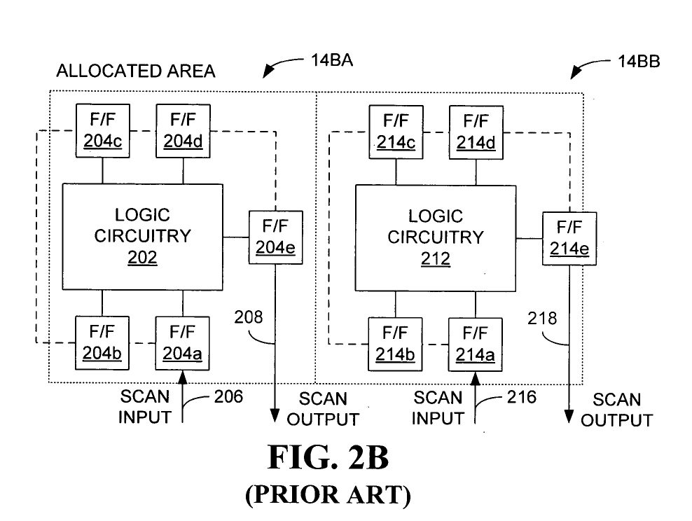

Note, in contrast to the IC of FIG. 2A, which contains no provision for test circuitry such as scan flip-flops and scan input and scan output ports, that the IC of FIG. 4 contains all of the circuitry, wiring, and connections to enable scan testing. The presence of these elements in the netlist prior to placement allows appropriate resources (e.g. area, power supply, clock distribution, etc.) to be budgeted, whereas their omission prior to placement necessitates their addition afterwards, which could then violate the constraints on area and power allocation. Also note, in contrast to the IC of FIG. 2B, in which the design area allocated for sub-sub-blocks 14BA and 14BB had been exceeded, use of the described embodiment results in the allocated design area not being exceeded. Specifically, the removal of the hierarchical boundary between the two sub-sub-blocks 14BA and 14BB and their resultant merger into a single sub-sub-block 140BAB allows the use of a single scan chain and only one set of scanin and scanout ports instead of two sets, which fits into the allocated area.

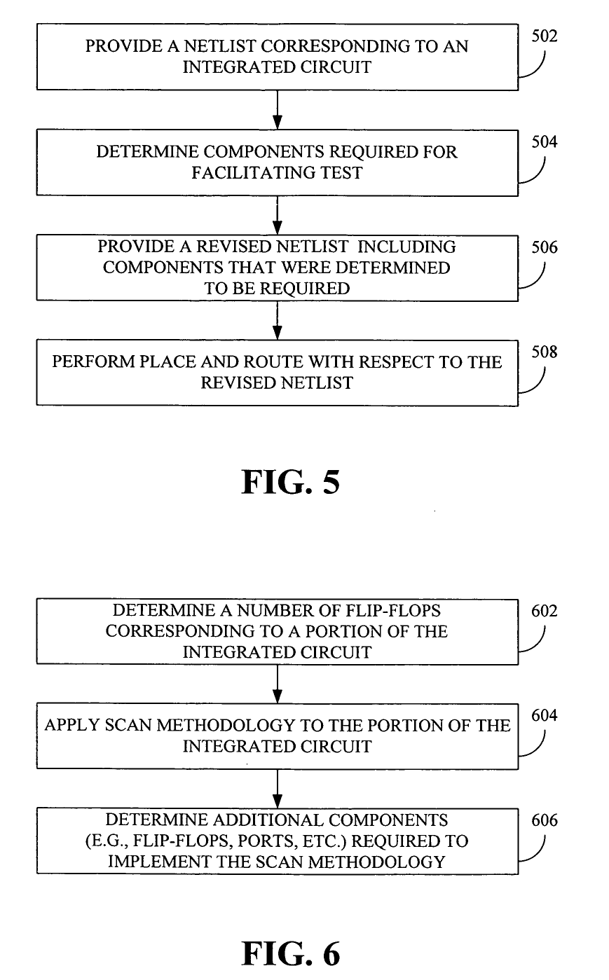

FIG. 5 is a flowchart depicting an embodiment of a method for designing integrated circuits. As shown in FIG. 5, the method may be construed as beginning at block 502, where a netlist corresponding to an IC is provided. In block 504, components required for facilitating test of the IC are determined. In block 506, a revised netlist including the components that were determined to be required for test is provided. Then, in block 508, place and route is performed with respect to the revised netlist.

As should be understood, various components can be provided in an IC to facilitate various tests. Examples of these components include but are not limited to test points, Built-In-Self-Test structures, isolation wrappers, clock control logic, analog-to-digital and digital-to-analog converters, and circuitry, wires, and connections that implement selected test methodologies. Analysis of the netlist in block 504 results in the determination of which components need to be added at which points in the original circuit, and the revised circuit, with the associated modifications, is produced in block 506. The netlist modifications include but are not limited to the alteration of circuit hierarchy, the addition or deletion of ports, the addition or deletion of logic gates or flip-flops, the addition or deletion of wiring and connections, and the insertion of additional circuits.

FIG. 6 is a flowchart depicting an embodiment of a method for designing ICs that involves the use of flip-flops for facilitating scan testing. Note that the blocks depicted in FIG. 6 can be attributed to the functionality described above with respect to block 504 of FIG. 5.

As shown in FIG. 6, the method may be construed as beginning at block 602, where a number of flip-flops corresponding to a portion of the IC are determined. In block 604, a scan methodology is applied to the portion of the integrated circuit. Specifically, with respect to a particular scan methodology, a certain number of flip-flops are used for each hierarchical block identified in that portion of the IC. Then, such as depicted in block 606, additional components that are required to implement the selected scan methodology are determined. By way of example, such components can include flip-flops, ports, and/or connections in addition to those previously provided in the design. As mentioned before with respect to FIG. 5, the IC netlist can be revised to include the additional components and place and route can be performed using the revised netlist.

The organization of flip-flops into a plurality of scan chains of desired lengths, along with the associated addition of scan input and output ports at appropriate points in the hierarchical netlist and perhaps even the addition of new flip-flops to balance scan chain lengths, constitute an illustrative example of the action performed in block 606. The exact interconnection of these elements (i.e., the ordering of the scan flip-flops) may be deferred until after the physical placement step (referred to in block 508), as is well known in the art, but the presence of these elements should be specified, as in block 606.

Note that the functionality associated with embodiments of methods for designing ICs can be embodied in systems that are implemented in software, hardware and/or combinations thereof. When implemented in hardware, embodiments of systems for designing ICs can be implemented with one or a combination of various technologies. By way of example, the following technologies, which are each well known in the art, can be used: a discrete logic circuit(s) having logic gates for implementing logic functions upon data signals, an application specific integrated circuit(s) (ASIC) having appropriate combinational logic gates, a programmable gate array(s) (PGA), and a field programmable gate array(s) (FPGA).

When implemented in software, embodiments of such a system can be stored on any computer-readable medium for use by or in connection with any computer-related system. In the context of this document, a computer-readable medium is an electronic, magnetic, optical, or other physical device or means that can contain or store a computer program for use by or in connection with a computer-related system. For example, a computer-readable medium can be any means that can store, communicate, propagate, or transport a computer program for use by or in connection with an instruction execution system, apparatus or device. The computer-readable medium can be, for example but not limited to, an electronic, magnetic, optical, electromagnetic, infrared, or semiconductor system, apparatus, device or propagation medium.

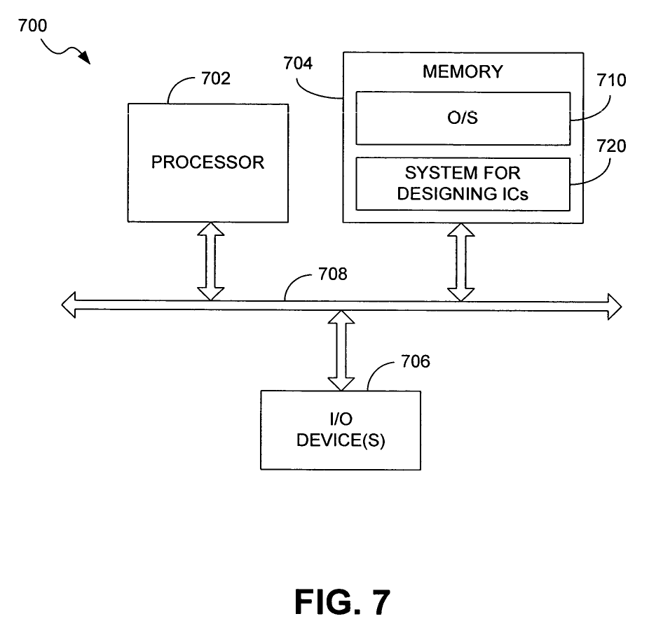

An embodiment of a system for designing ICs that is implemented in software is depicted schematically in FIG. 7, where the system is associated with a computer or processor-based system 700. Generally, computer 700 includes a processor 702, memory 704, and one or more input and/or output (I/O) devices 706 (or peripherals) that are communicatively coupled via a local interface 708. The software in memory 704 can include one or more separate programs, each of which comprises an ordered listing of executable instructions for implementing logical functions. In the example of FIG. 7, the software in the memory 704 includes an operating system (O/S) 710 and a system for designing ICs 720.

It should be emphasized that variations and modifications may be made to the above-described embodiments. For example, although the flowcharts described above have been limited to describing particular aspects of several select embodiments, it should be understood that one or more additional functions associated with the design of ICs also can be implemented in other embodiments. For instance, logic synthesis and/or generation of netlists can be facilitated by some embodiments. All such modifications and variations are intended to be included herein within the scope of this disclosure and protected by the following claims.

1. A method for designing an integrated circuit (IC), said method comprising:
providing a netlist;
determining components required to implement test of at least a portion of the integrated circuit defined by the netlist;
providing a revised netlist including the components determined; and
performing a place and route operation with respect to the revised netlist.

2. The method of claim 1, wherein providing a netlist comprises generating a synthesized netlist.

3. The method of claim 1, wherein determining components comprises:
determining a number of flip-flops corresponding to the portion of the IC;
applying at least a first scan methodology to the portion of the IC; and
determining additional components required to implement the first scan methodology.

4. The method of claim 1, wherein determining components comprises organizing flip-flops into a plurality of scan chains of desired lengths.

5. The method of claim 1, wherein determining components comprises adding scan input and scan output ports to the netlist.

6. The method of claim 1, wherein determining components comprises adding flip-flops to alter scan chain lengths.

7. The method of claim 1, wherein determining components comprises altering at least one of hierarchy, circuitry, wiring, and connections with respect to the netlist.

8. The method of claim 1, wherein performing place and route functionality comprises ensuring that IC design criteria associated with timing, area and power requirements are satisfied.

9. The method of claim 1, wherein determining components is performed prior to performing a place and route operation of the IC.

10. The method of claim 1, wherein determining components is performed prior to placement but further specification of component interconnection is performed after placement and before routing.

11. An integrated circuit formed by the method of claim 1.

12. A computer-readable medium having stored thereon information for performing a computer-implemented method, the method comprising:
providing a netlist;
determining components required to implement test of at least a portion of the integrated circuit defined by the netlist;
providing a revised netlist including the components determined; and
performing a place and route operation with respect to the revised netlist.

13. A system for designing an integrated circuit (IC), said system comprising:
a processor operative to execute instructions; and
a memory communicating with the processor and storing instructions for:
providing a netlist;
determining components required to implement test of at least a portion of the integrated circuit defined by the netlist;
providing a revised netlist including the components determined; and
performing a place and route operation with respect to the revised netlist.

14. The system of claim 13, further comprising:
means for outputting the revised netlist.

15. The system of claim 13, further comprising:
a display device communicating with the processor and operative to output the revised netlist.
